(19) United States
(12) Patent Application Publication
(10) Pub. No.: US 2001/0020535 A1
(43) Pub. Date: Sep. 13, 2001

(54) Circuit pack, multilayer printed wiring board, and device

(75) Inventors: Takatoshi Takahashi, Tokyo (JP); Akihiko Tsukui, Tokyo (JP); Junya Sakurai, Tokyo (JP)

Correspondence Address: OSTROLENK FABER GERB & SOFFEN, 1180 AVENUE OF THE AMERICAS, NEW YORK, NY, 100368403

(73) Assignee: NEC Corporation

(21) Appl. No.: 09/802,141

(22) Filed: Mar. 8, 2001

(30) Foreign Application Priority Data
Mar. 8, 2000 (JP) 2000-063180

(51) Int. Cl. H01L 23/02

(52) U.S. Cl. 174/52.4

(57) ABSTRACT

A technique is provided that can shorten electrical connections between elements of a device and terminals of a printed wiring board. The multilayer printed wiring board has a recess and comprises connection terminals of wiring films disposed in the recess and exposed from the recess. The device comprises connection terminals of an element disposed in the recess and exposed from the recess.

### BACKGROUND OF THE INVENTION

The present invention relates to a circuit pack, to a multilayer printed wiring board, and to a device.

Structures each in which semiconductor devices such as LSIs are mounted on a multilayer printed wiring board are well known. In such a circuit pack, an LSI and a printed wiring board are electrically interconnected via through holes formed in the printed wiring board.

For example, JP-No. 275677/1994 discloses that a multilayer printed wiring board has a hole formed therein and a semiconductor chip is disposed in the hole.

In this printed wiring board, connection terminals to be electrically connected with semiconductor chips on the printed wiring board are not exposed in holes. In a manner similar to that of the conventional method, a semiconductor chip is electrically connected to a printed wiring board via through-holes formed on the printed wiring board.

However, such a conventional method makes the connection portion longer by the length of the through hole. This longer connection portion increases the electrical loss and may cause occurrence of crosstalk.

### SUMMARY OF THE INVENTION

The present invention is made to solve the above-mentioned problems.

An objective of the present invention is to provide a technique of shortening electrical connections between elements of a device and terminals of a printed wiring board.

Another objective of the present invention is to provide a technique of shortening electrical connections between elements of a device and terminals of a printed wiring board and of reducing electrical losses and possible crosstalk.

Further another objective of the present invention is to provide a technique of providing good workability when a device is mounted on a printed wiring board.

Still another objective of the present invention is to provide a technique of, when terminals of a device and terminals of a printed wiring board are soldered, with the device mounted on the printed wiring board, preventing adjacent terminals from being electrically connected by running of solder.

The former three objectives are achieved by a multilayer printed wiring board, wherein at least two wiring film layers are laminated, the multilayer printed wiring board having a recess therein. The multilayer printed wiring board comprises connection terminals of the wiring film layers disposed in the recess and exposed from the recess.

In a specific structure of the multilayer printed wiring board, the recess is formed in a stepwise structure. The connection terminals are exposed on a flat surface of the stepwise structure.

A device comprises an element, a package, a protrusion disposed on the package, and connection terminals of the element, disposed in the protruded portion and exposed from the protruded portion.

In a specific structure of the device, the protrusion of the package has a stepwise structure. The connection terminals are exposed on each flat surface of the stepwise structure.

Particularly, in a circuit pack on which the above-mentioned device is mounted on the above-mentioned multilayer printed wiring board, the protrusion is disposed in the recess of the multilayer printed wiring board. The connection terminals of the device are connected to connection terminals of the multilayer printed wiring board.

In the circuit pack, the connection terminals of the device and the connection terminals of the multilayer printed wiring board are confronted and directly connected to each other via no through holes.

The above-mentioned structure allows the terminals of elements of a device to be directly connected to terminals of a multilayer printed wiring board, thus shortening the electrical connection. Hence, this structure can reduce electrical loses and possible crosstalk.

Moreover, insertion of the protrusion of the device into the recess of the multilayer printed wiring board facilitates the positioning of the components. This feature can provide good workability when the device is mounted on the printed wiring board.

Moreover, in the multilayer printed wiring board, an insulating wall for preventing running of solder is preferably disposed on the side of (e.g. around) the exposed connection terminals. This solder-running prevention wall can achieve the last mentioned objective of the invention.

In the circuit pack, the last mentioned objective is achieved by an insulating member disposed between a connection terminal (A) of the multilayer printed wiring board and a connection terminal (B) adjacent to the connection terminal (A). The insulating member forms a portion of the multilayer printed wiring board and/or a portion of the device.

In the circuit pack, the last mentioned objective is achieved by an insulating member disposed between a connection terminal (C) of the device and a connection terminal (D) adjacent to the connection terminal (C). The insulating member forms a portion of the multilayer printed wiring board and/or a portion of the device.

### BRIEF DESCRIPTION OF THE DRAWINGS

This and other objects, features and advantages of the present invention will become more apparent upon a reading of the following detailed description and drawings, in which;

FIG. 1 is a perspective view illustrating a multilayer printed wiring board according to a first embodiment of the present invention;

FIG. 2 is a perspective view illustrating the device according to the first embodiment of the present invention;

FIG. 3 is an explanatory diagram explaining the step of mounting a device on a multilayer printed wiring board according to the first embodiment of the present invention;

FIG. 4 is a cross-sectional view illustrating a circuit pack according to the first embodiment of the present invention;

FIG. 5 is a perspective view illustrating a multilayer printed wiring board according to a second embodiment of the present invention;

FIG. 6 is a perspective view illustrating a device according to the second embodiment of the present invention;

FIG. 7 is a cross-sectional view illustrating a circuit pack according to the second embodiment of the present invention;

FIG. 8 is a perspective view illustrating a multilayer printed wiring board according to a third embodiment of the present invention;

FIG. 9 is a perspective view illustrating a device according to the third embodiment of the present invention; and

FIG. 10 is a cross-sectional view illustrating a circuit pack according to the third embodiment of the present invention.

### DESCRIPTION OF THE EMBODIMENTS

According to the present invention, a multilayer printed wiring board includes wiring films of two layers or more. A recess is formed in the multilayer printed wiring board. Connection terminals of wiring films are disposed and exposed in the recess. For example, the recess is shaped in a stepwise form. The connection terminals are exposed on the flat surface of each step of the stepwise recess. Insulating walls for preventing a run of solder are disposed on the side of (or around) the connection terminals exposed in the recess.

According to the present invention, a device includes an element and a package. The device has a protrusion disposed in the package and connection terminals disposed on and exposed from the protrusion. For example, the package has a protrusion shaped in a stepwise form. The connection terminals are exposed on the flat surface of each step of the protrusion.

In a circuit pack according to the present invention, the device is mounted on the multilayer printed wiring board. The protrusion of the device is inserted into the recess formed in the printed wiring board. The connection terminals of the device are directly connected to the connection terminals of the multilayer wiring board, in a confronting state and via no through holes. An insulating member forming portion(s) of the multilayer printed wiring board and/or the device is formed between the connection terminals (A) of the multilayer printed wiring board and the connection terminals (B) adjacent to the connection terminals (A). An insulating member forming portion(s) of the multilayer printed wiring board and/or the device is formed between the connection terminals (C) of the device and the connection terminals (D) adjacent to the connection terminals (C).

The present invention will be described below in more detail.

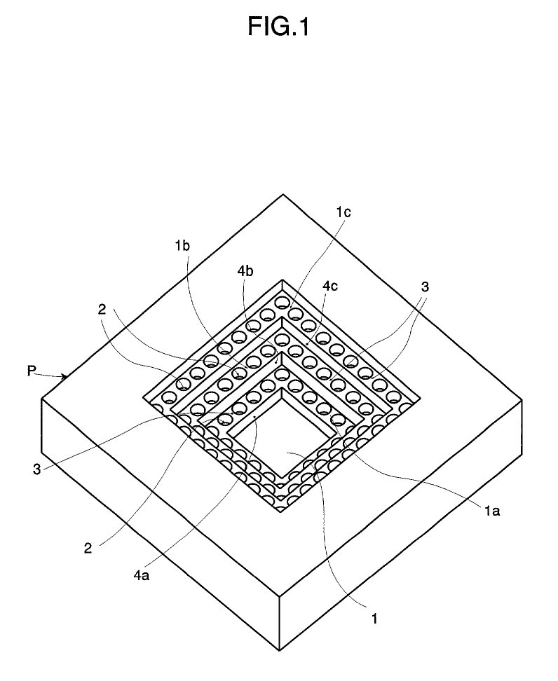

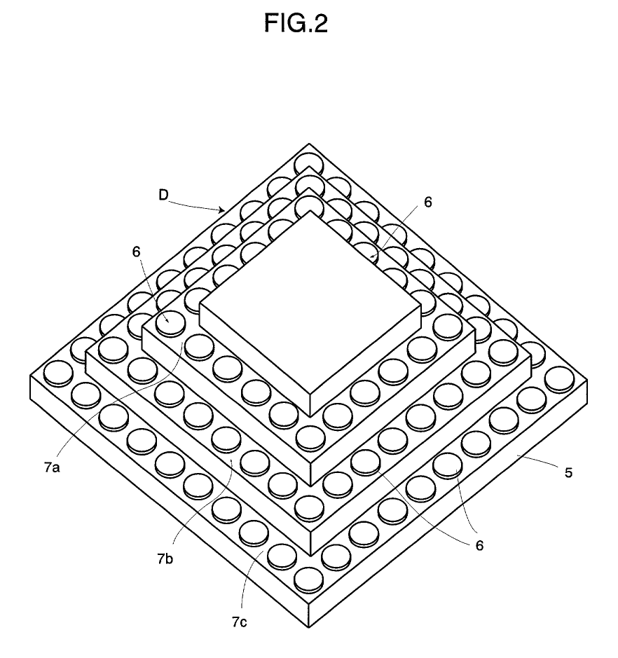

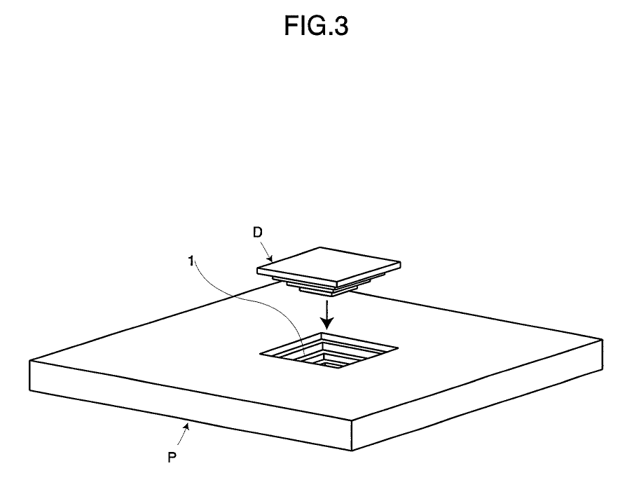

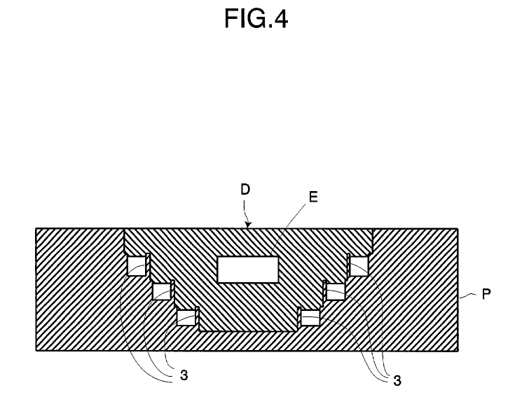

A first embodiment of the present invention is shown in FIGS. 1 to 4. FIG. 1 is a perspective view illustrating a multilayer printed wiring board according to a first embodiment of the present invention. FIG. 2 is a perspective view illustrating a device according to the present invention. FIG. 3 is an explanatory diagram explaining the step of mounting a device on a multilayer printed wiring board according to the first embodiment of the present invention. FIG. 4 is a cross-sectional view illustrating a circuit pack according to the first embodiment of the present invention.

In the embodiment, the multilayer printed wiring board (P), as shown in FIG. 1, is characterized by two or more layer wiring films, for example, three layered wiring films. Wiring films having a desired number of layers may be formed.

The multilayer printed wiring board (P) has a stepped recess 1. The terminals (connection terminals) 2 connected to wiring films are exposed at horizontal flat surfaces 1a, 1b and 1c in the stepped recess 1.

Walls 3 are formed between a connection terminal 2 and adjacent terminals 2.

The walls 3 are respectively formed of insulating films 4a, 4b and 4c formed on the wiring films. That is, through holes corresponding to connection terminals 2 are formed in each of the insulating films 4a, 4b and 4c. Each connection terminal 2 is exposed in the corresponding through hole only. The wall 3 around each through hole cuts off the corresponding connection terminal 2 from all neighboring connection terminals 2.

Other portions are basically identical to those of the conventional multilayer wiring board.

The device (D) is similar to the conventional device in that the device (D) includes an element (E) such as a semiconductor element and a package incorporating the element (E).

However, in the device (D), as understood from FIG. 2, the package 5 has a stepped protrusion. Terminals (connection terminals) 6 of the element are exposed on the horizontal flat portions 7a, 7b and 7c of the stepped protrusion.

The connection terminals 6 slightly protrude from the surfaces of the flat portions 7a, 7b and 7c. Each connection terminal 6 can be fitted into a through hole formed in each of the insulating films 4a, 4b and 4c of the multilayer printed wiring board (P).

The device (D) is mounted on the multilayer printed wiring board (P), as follow:

The stepped protrusion of the device D is inserted into the stepped recess of the multilayer printed wiring board (P). Connection terminals 6 of the device (D) are inserted into the through holes formed in the insulating films 4a, 4b and 4c of the multilayer printed wiring board (P). The connection terminals 6 and 2 confront each other.

A combination of the device (D) and the multilayer printed wiring board (P) is heated in a heating oven to carry out a reflowing process. The solder previously placed on the connection terminals 2 melts to mutually bond the connection terminals 2 and 6.

In the soldering connection, since the molten solder is trapped in the hole, the trouble does not occur that a run of the solder interconnects adjacent connection terminals 2. The connection terminals 6 of the device (D) and the connection terminal 2 of the multilayer printed wiring terminals 2 are respectively connected directly one another. This method can realize very short connection, compared with the conventional technique of performing connection via through-holes. Hence, this method can reduce the electrical loss, possible crosstalk, or variations in frequency characteristics.

The connection terminals 6 of the device (D) and the connection terminals 2 of the multilayer printed wiring board (P) are interconnected three-dimensionally. This can increase the number of connections, compared with connection on a two-dimensional plane, thus realizing a high-density assembly.

The device (D) can be mounted on the multilayer wiring board (P), with the recess and the protrusion aligned with each other, so that good mounting workability can be provided.

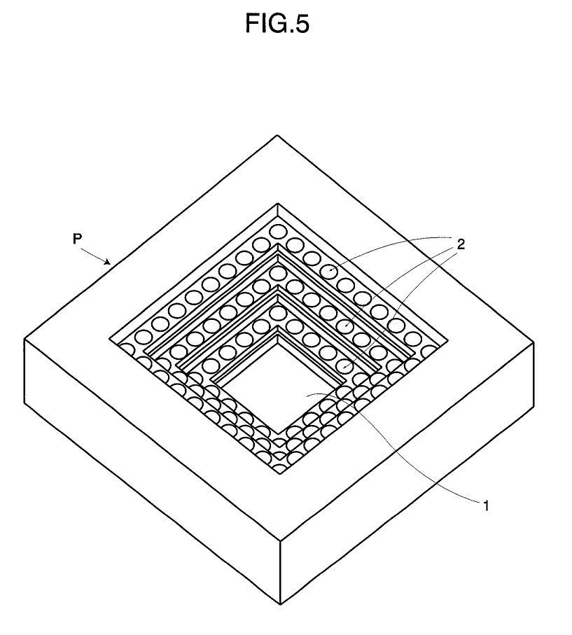

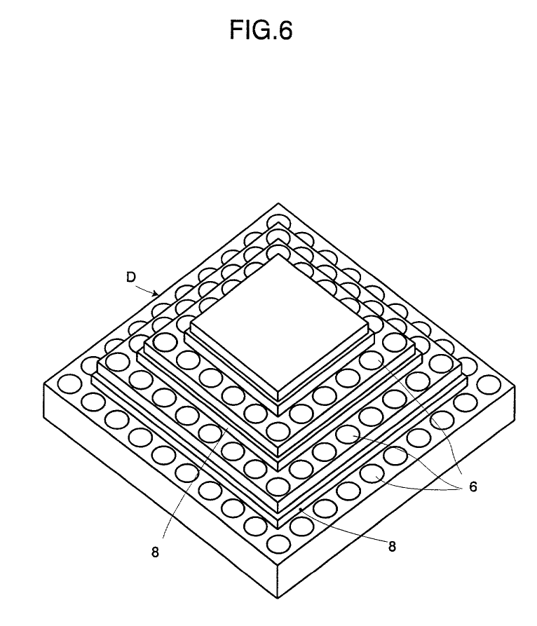

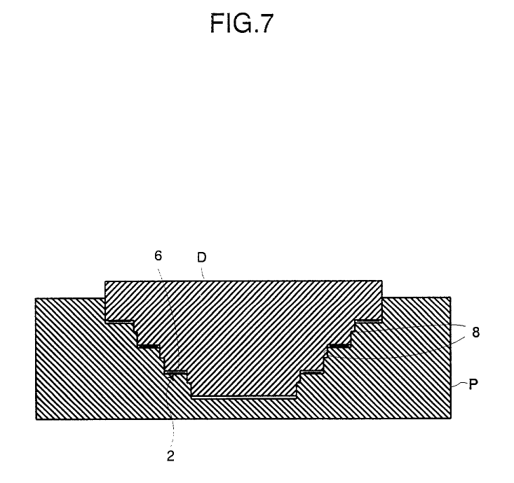

A second embodiment of the present invention will be described by referring to FIGS. 5 to 7. FIG. 5 is a cross-sectional view illustrating a multilayer printed wiring board according to the second embodiment of the present invention. FIG. 6 is a cross-sectional view illustrating a device according to the second embodiment of the present invention. FIG. 7 is a cross-sectional view illustrating a circuit pack according to the second embodiment of the present invention.

The second embodiment differs from the first embodiment in the following respects. Other configurations are basically identical to those of the first embodiment and hence the detail explanation will be omitted here.

In the second embodiment, a wall 3 is not disposed between connection terminals 2 formed on the same flat surface of each step of the multilayer printed wiring board (P). That is, an insulating film is not formed around each terminal 2. Each connection terminal 2 is slightly raised from the horizontal flat surface in the stepped recess 1.

A wall 8 is placed between the connection terminals 6 stepped in the device (D) to prevent a run of solder.

Where the device is mounted on the multilayer printed wiring board (P), an insulating material forming a portion of the multilayer printed wiring board (P) or the device (D) is provided between the connection terminals 2 (6) in a stepped state.

This structure can prevent a run of solder from making an electrical short circuit between a connection terminal and an adjacent lower connection terminal. This embodiment has advantages similar to those in the first embodiment.

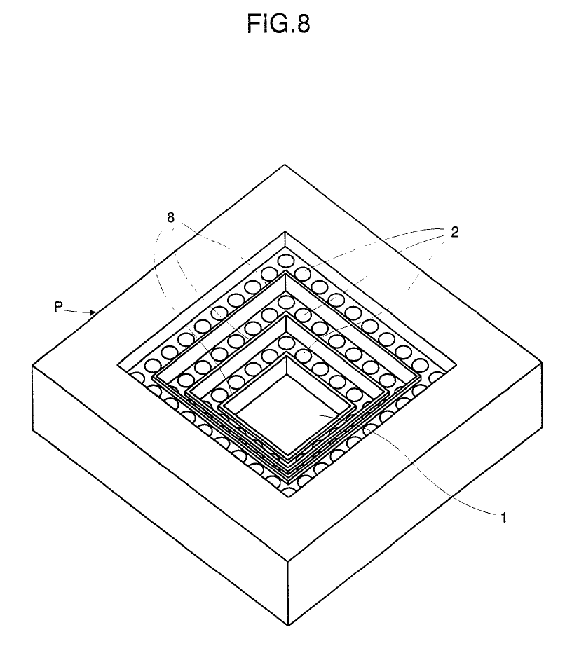

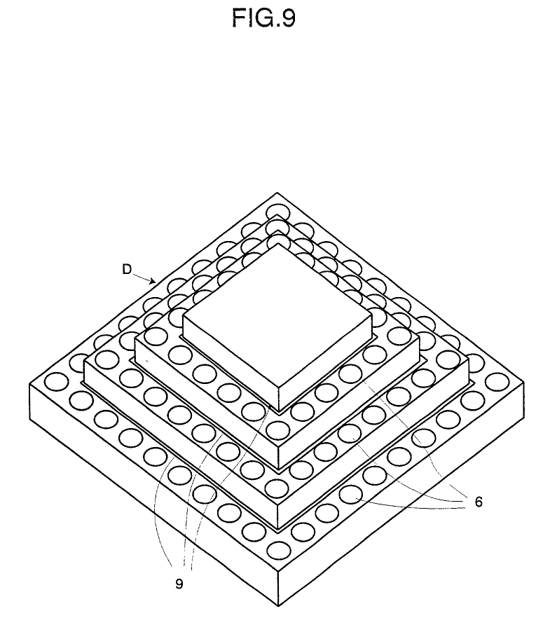

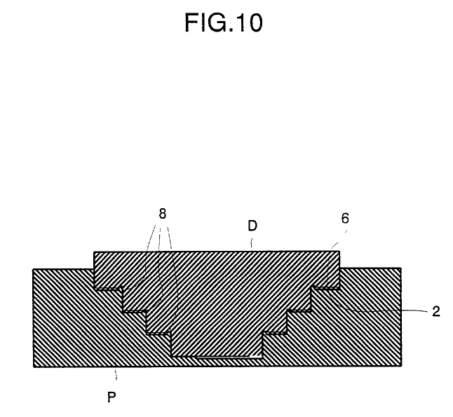

A third embodiment of the present invention is shown in FIGS. 8 to 10. FIG. 8 is a cross-sectional view illustrating a multilayer printed wiring board according to the third embodiment of the present invention. FIG. 9 is a cross-sectional view illustrating a device according to the third embodiment of the present invention. FIG. 10 is a cross-sectional view illustrating a circuit pack according to the third embodiment of the present invention.

The third embodiment differs from the first embodiment in that a wall 8 is formed on the corner of each step in the recess 1 of a multilayer printed wiring board to prevent a run of solder. Moreover, the device (D) has a groove 9 into which the wall 8 is inserted when the device (D) is mounted on the multilayer printed wiring board. Other portions are basically identical to those in the above-mentioned embodiments. Hence, the detail explanation is omitted here.

In the above-mentioned multilayer printed wiring board, the connection terminals are exposed through, for example, a laser material processing. Alternatively, in order to pile up layers, each layer may be patterned using the laser material processing.

In the device (D) with the above-mentioned structure, a material (e.g. ceramic) for a package may be previously processed as shown in FIGS. 8 to 10.

According to the present invention, the electrical connections between elements in the device and the printed wiring board can be shortened. This can reduce the electrical loss and possible crosstalk, and variations in frequency characteristic. Moreover, the present invention provides good workability when a device is mounted on a printed wiring board. In soldering between terminals, the present invention can prevent a run of solder from making an electrical short circuit between adjacent terminals.

The entire disclosure of Japanese Application No. 2000-063180 filed Mar. 8, 2000 including specification, claims, drawings and summary are incorporated herein by reference in its entirely.

What is claimed is:

1. A multilayer printed wiring board, wherein at least two wiring film layers are laminated, said multilayer printed wiring board having a recess therein; said multilayer printed wiring board comprising connection terminals of said wiring film layers disposed in said recess and exposed from said recess.

2. The multilayer printed wiring board defined in claim 1, wherein said recess is formed in a stepwise structure; and wherein said connection terminals are exposed on a flat surface of said stepwise structure.

3. The multilayer printed wiring board defined in claim 1, further comprising an insulating walls disposed on the side of said connection terminals, for preventing solder from running.

4. A device comprising:
an element;
a package;
a protrusion disposed on said package; and
connection terminals of said element, disposed in said protruded portion and exposed from said protruded portion.

5. The device defined in claim 4, wherein said protrusion of said package has a stepwise structure; and wherein said connection terminals are exposed on each flat surface of said stepwise structure.

6. A circuit pack wherein a device is mounted on a multilayer printed wiring board; said multilayer printed wiring board having a recess and connection terminals formed of wiring film and exposed in said recess; said wiring film being formed of two or more laminated layers; said device including a package, a protrusion disposed in said package, an element, and connection terminals exposed on said protrusion; said protrusion being disposed in said recess of said multilayer printed wiring board; said connection terminals of said device being connected to connection terminals of said multilayer printed wiring board.

7. The circuit pack defined in claim 6, wherein said recess has a stepwise structure; and wherein said connection terminals are exposed on each flat surface of said stepwise structure.

8. The circuit pack defined in claim 6, further comprising an insulating wall disposed on the side of said connection terminals, for preventing solder from running.

9. The circuit pack defined in claim 6, wherein said protrusion has a stepwise structure; and wherein said connection terminals are exposed on each flat surface of said stepwise structure.

10. The circuit pack defined in claim 6, wherein said connection terminals of said device and said connection terminals of said multilayer printed wiring board are confronted and directly connected to each other via no through holes.

11. The circuit pack defined in claim 6, further comprising an insulating member disposed between a connection terminal (A) of said multilayer printed wiring board and a connection terminal (B) adjacent to said connection terminal (A), said insulating member forming a portion of said multilayer printed wiring board and/or a portion of said device.

12. The circuit pack defined in claim 6, further comprising an insulating member disposed between a connection terminal (C) of said device and a connection terminal (D) adjacent to said connection terminal (C), said insulating member forming a portion of said multilayer printed wiring board and/or a portion of said device.
